(19) United States
(12) Patent Application Publication
(10) Pub. No.: US 2026/0239900 A1
(43) Pub. Date: Aug. 13, 2026

(54) METHODS AND SYSTEMS FOR FILLING A GAP

(71) Applicant: ASM IP Holding, B.V., Almere (NL)

(72) Inventors: René Henricus Jozef Vervuurt, Leuven (BE); Timothee Blanquart, Oud-Heverlee (BE); Viljami Pore, Helsinki (FI); Yu Xu, Vantaa (FI)

(21) Appl. No.: 19/645,575

(22) Filed: Apr. 13, 2026

Related U.S. Application Data
(62) Division of application No. 17/708,299, filed on Mar. 30, 2022.
(60) Provisional application No. 63/170,249, filed on Apr. 2, 2021.
(60) Provisional application No. 63/250,816, filed on Sep. 30, 2021.

(51) Int. Cl. H10P 14/60; C23C 16/40; C23C 16/455; C23C 16/50; C23C 16/52; H01J 37/32; H10P 14/692; H10W 20/00

(52) U.S. Cl. CPC H10P 14/6532; C23C 16/405; C23C 16/45527; C23C 16/45565; C23C 16/50; C23C 16/52; H01J 37/32357; H01J 37/32449; H10P 14/6339; H10P 14/69394; H10W 20/098; H01J 2237/3321

(57) ABSTRACT

Disclosed are methods and systems for filling a gap. The methods and systems are useful, for example, in the field of integrated circuit manufacture.

### CROSS-REFERENCE TO RELATED APPLICATIONS

This application is a divisional of, and claims priority to, U.S. patent application Ser. No. 17/708,299 filed Mar. 30, 2022 titled METHODS AND SYSTEMS FOR FILLING A GAP; which claims priority to U.S. Provisional Patent Application Ser. No. 63/170,249, filed Apr. 2, 2021, titled METHODS AND SYSTEMS FOR FILLING A GAP; and U.S. Provisional Patent Application Ser. No. 63/250,816, filed Sep. 30, 2021, titled METHODS AND SYSTEMS FOR FILLING A GAP; the disclosures of which are hereby incorporated by reference in their entirety.

### FIELD OF INVENTION

The present disclosure generally relates to the field of semiconductor processing methods and systems, and to the field integrated circuit manufacture. In particular, methods and systems suitable for filling a gap are disclosed.

### BACKGROUND OF THE DISCLOSURE

The scaling of semiconductor devices, such as, for example, logic devices and memory devices, has led to significant improvements in speed and density of integrated circuits. However, conventional device scaling techniques face significant challenges for future technology nodes.

For example, one challenge has been finding suitable ways of filling gaps such as recesses, trenches, vias and the like with a material without formation of any gaps or voids.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods of filling a gap, to structures and devices formed using such methods, and to apparatus for performing the methods and/or for forming the structures and/or devices. The layers may be used in a variety of applications. For example, they may be used in the field of integrated circuit manufacture.

Thus described herein is a method of filling a gap. The method comprises providing a substrate to a reaction chamber. The substrate is provided with a gap. The method further comprises depositing a convertible layer on the substrate, and exposing the substrate to active species. By exposing the substrate to an active species, at least part of the convertible layer is converted into a gap filling fluid that at least partially fills the gap.

In some embodiments, converting at least a part of the convertible layer into a gap filling fluid comprises liquefying the convertible layer.

In some embodiments, the convertible layer comprises a volatilizable element, and converting at least a part of the convertible layer into a gap filling fluid comprises: volatilizing the volatilizable element and forming a volatilized vapor; and, condensing the volatilized vapor, thereby forming the gap filling fluid.

In some embodiments, the method further comprises solidifying the gap filling fluid, thereby filling the gap with a solidified material.

In some embodiments, the active species comprises fluorine.

In some embodiments, the convertible layer is selected from a metal, a metal alloy, a metal oxide, and a metal nitride.

In some embodiments, the convertible layer comprises a metal oxide that comprises a metal and oxygen, and depositing the metal oxide on the substrate comprises one or more metal oxide deposition sub cycles. A metal oxide deposition sub cycle comprises a metal precursor pulse that comprises exposing the substrate to a metal precursor that comprises the metal; and, an oxygen reactant pulse that comprises exposing the substrate to an oxygen reactant that comprises the oxygen.

In some embodiments, a method as described herein comprises a plurality of redeposition cycles. A redeposition cycle comprising the steps of depositing a convertible layer on the substrate and exposing the substrate to the active species.

In some embodiments, the method further comprises a step of converting the gap filling fluid into a converted material.

In some embodiments, the step of converting the gap filling fluid into the converted material comprises a step of exposing the substrate to a direct plasma.

In some embodiments, the direct plasma is a direct oxygen plasma.

In some embodiments, the direct plasma is a direct nitrogen plasma.

In some embodiments, a method as described herein comprises executing a plurality of conversion cycles. A conversion cycle comprises exposing the substrate to the active species; and, converting the gap filling fluid into a converted material.

In some embodiments, a method as described herein comprises executing a plurality of super cycles. A super cycle comprises depositing a convertible layer on the substrate; exposing the substrate to the active species; and, converting the gap filling fluid into a converted material.

In some embodiments, the metal oxide comprises titanium oxide, and the metal comprises titanium.

In some embodiments, the metal precursor is selected from a halide, an oxyhalide, and an organometallic compound.

In some embodiments, the metal precursor comprises a titanium beta-diketonate.

Further described is a field effect transistor that comprises a gate contact at least a part of which is formed according to a method as described herein.

Further described is a metal contact comprising a layer that is deposited by means of a method as described herein.

Further described is a system that comprises a reaction chamber, a precursor gas source that comprises a metal precursor, a deposition reactant gas source that comprises a deposition reactant, an active species source that is arranged for providing an active species, a conversion reactant source that is arranged for providing a conversion reactant, and a controller. The controller is configured to control gas flow into the reaction chamber to form a layer on a substrate by means of a method as described herein.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates an embodiment of a method as disclosed herein.

FIG. 2 illustrates an embodiment of a method as disclosed herein.

FIG. 3 shows a schematic representation of an embodiment of a method as described herein.

FIG. 4 schematically shows another embodiment of a method as described herein.

FIG. 5 illustrates the operation of a method as described herein.

FIG. 6 shows micrographs of structures formed using an embodiment of a method as described herein.

FIG. 7 illustrates a system (700) in accordance with yet additional exemplary embodiments of the disclosure.

FIG. 8 shows another embodiment of a system (800) as described herein in a stylized way.

FIG. 9 shows a stylized representation of a substrate (900) comprising a gap (910).

FIGS. 10-12 shows schematic representations of embodiments of systems (1000, 1100, 1200) as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include at least one of bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

As used herein, a “structure” can be or can include a substrate as described herein. Structures can include one or more layers overlying the substrate, such as one or more layers formed according to a method as described herein. Device portions can be or include structures.

The term “deposition process” as used herein can refer to the introduction of precursors (and/or reactants) into a reaction chamber to deposit a layer over a substrate. “Cyclical deposition processes” are examples of “deposition processes”.

As used herein, the term “gap filling fluid”, also referred to as “flowable gap fill”, may refer to a composition of matter that is liquid, or that can form a liquid, under the conditions under which is formed and which has the capability to form a solid film. A “gap filling fluid” can, in some embodiments, be only temporarily in a flowable state, for example when the “gap filling fluid” is temporarily formed through formation of liquid oligomers from gaseous monomers during a polymerization reaction, and the liquid oligomers continue to polymerize to form a solid polymeric material. For ease of reference, a solid material formed from a gap filling fluid may, in some embodiments, be simply referred to as “gap filling fluid”.

A method as described herein can comprise depositing a layer by means of a cyclic deposition process. The term “cyclic deposition process” or “cyclical deposition process” can refer to a sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

A method as described herein can comprise depositing a layer by means of an atomic layer deposition process. The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element that may be incorporated during a deposition process as described herein.

The term “oxygen reactant” can refer to a gas or a material that can become gaseous and that can be represented by a chemical formula that includes oxygen. In some cases, the chemical formula includes oxygen and hydrogen.

The term “nitrogen reactant” can refer to a gas or a material that can become gaseous and that can be represented by a chemical formula that includes nitrogen. In some cases, the chemical formula includes nitrogen and hydrogen.

Further, in this disclosure, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

In this disclosure, any defined meanings do not necessarily exclude ordinary and customary meanings, in some embodiments.

Described herein is a method of filling a gap. The gap is comprised in a substrate. The method comprises providing a substrate to a reaction chamber. Then, a convertible layer is deposited on the substrate. The convertible layer can suitably be deposited using a deposition technique that yields conformal layers, such as atomic layer deposition (ALD) or another cyclical deposition process. Alternatively, the convertible layer can be deposited using a deposition technique that yields non-conformal layers, i.e. non-uniform layers, such as layers that have a higher thickness on a flat surface of a substrate, than inside a gap or trench; or layers that have a higher thickness inside a gap or trench than on a flat surface of a substrate. Examples of techniques that can yield non-conformal layers are chemical vapor deposition and plasma-enhanced chemical vapor deposition. Then, the substrate is exposed to an active species. Thus, at least a part of the convertible layer is converted into a gap filling fluid. The gap filling fluid is then solidified, such that the gap is filled with a solidified material.

In some embodiments, the convertible layer is conformally deposited on the substrate. In other words, the convertible layer can have a thickness which is constant over the surface of the substrate, including in gaps, recesses, and the like, e.g. within a margin of error of 50%, 20%, 10%, 5%, 2%, 1%, 0.5%, or 0.1%.

In some embodiments, the convertible layer is deposited by means of a deposition method that yields a growth rate at a distal surface of a gap that is higher than a growth rate at a proximal surface of the gap. In some embodiments, the growth rate at the distal surface of the gap is from at least 200% to at most 500, or from at least 100% to at most 200%, or from at least 50% to at most 100%, or from at least 20% to at most 50%, or from at least 10% to at most 20%, or from at least 5% to at most 10%, or from at least 2% to at most 5%, or from at least 1% to at most 2% higher than the growth rate at the proximal surface of the gap.

In some embodiments, the convertible layer comprises a volatilizable compound, i.e. a compound that can form a vapor when exposed to a suitable reactant. Accordingly, when the substrate is exposed to an active species, the volatilizable compound can be volatilized and a volatilized vapor can be formed. The volatilized vapor can then be condensed, such that a gap filling fluid, i.e. a liquid phase, is formed in the gap. The gap filling fluid is then solidified such that the gap is filled with a solidified material. Such embodiments notwithstanding, it shall be understood that, in some embodiments, the step of forming a volatilized vapor is omitted, and the convertible layer is directly converted into a gap filling fluid. In other words, the convertible layer can, in some embodiments, be liquefied upon exposure to the active species. Optionally, the gap filling fluid can then be solidified to form a solidified material in the gap.

In some embodiments, the gap filling fluid is formed wherever a convertible layer is present on the substrate. When the substrate has a surface that is completely covered by the convertible layer, a gap filling fluid can be formed over the entire substrate surface, both outside gaps and inside gaps comprised in the substrate. When the substrate has a surface that is only partially covered by the convertible layer, then the gap filling fluid can be preferentially formed only in those places where the convertible layer is present. When the gap filling fluid is formed both outside of the gaps and inside the gaps, the gap filling fluid can, in some exemplary modes of operation, be drawn into a gap by at least one of capillary forces, surface tension, and gravity. It shall be understood that a distal portion of the gap feature refers to a portion of the gap feature that is relatively far removed from a substrate's surface, and that the proximal portion of a gap feature refers to a part of the gap feature that is closer to the substrate's surface compared to the lower/deeper portion of the gap feature.

Further, it shall be understood that, in some embodiments, exposing the substrate to active species, optionally condensing the volatilized vapor, and solidifying the gap filling fluid occur at least partially simultaneously. In other words, exposing the substrate to active species, optionally condensing the volatilized vapor, and solidifying the gap filling fluid may, but do not necessarily, occur simultaneously.

The materials formed according to the present methods are highly advantageous, e.g. in the field of integrated circuit manufacture.

Suitable active species include ions and radicals. Suitable radicals include halogen radicals. In some embodiments, the active species comprises fluorine. Thus, in such embodiments, the volatilized vapor, the gap filling fluid, and the solidified material comprise a fluoride. Suitable fluorine-comprising active species include fluorine radicals.

In some embodiments, exposing the substrate to active species comprises generating a plasma in a remote plasma generator. The remote plasma generator is suitably positioned outside of the reaction chamber, and can be adjacent to the reaction chamber, or it can be positioned at a pre-determined distance from the reaction chamber. The remote plasma generator can be operationally connected with the reaction chamber via a reactive species duct such as a stainless steel pipe. Thus, reactive species, e.g. at least one of radicals and ions, can be brought from the remote plasma generator to the reaction chamber. Optionally, the reactive species duct can comprise one or more mesh plates. Mesh plates can advantageously block charged species, i.e. ions, while letting uncharged reactive species such as radicals pass. Thus, the substrate can be advantageously exposed to radicals only.

In some embodiments, the active species comprise fluorine radicals generated in a remote plasma source. For example, the remote plasma source can be provided with a plasma gas comprising NF₃. In some embodiments, the plasma gas comprises nitrogen, fluorine, and a noble gas such as argon (Ar). In some embodiments, the plasma gas comprises NF₃ and a noble gas such as Ar. Such a remote plasma source can suitably generate fluorine radicals that can be employed as an active species.

In some embodiments, NF₃ is provided to the remote plasma source at a flow rate of at least 0.01 sccm to at most 1000 sccm, or from at least 0.1 sccm to at most 100 sccm, or from at least 1 sccm to at most 10 sccm.

In some embodiments, a noble gas such as argon is provided to the remote plasma source at a flow rate of at least 0.001 slm to at most 100 slm, or of at least 0.01 slm to at most 10 slm, or of at least 0.1 slm to at most 1 slm.

In some embodiments, exposing the substrate to active species comprises generating a plasma in the reaction chamber. In other words, exposing the substrate to an active species can comprise exposing the substrate to a direct plasma.

In some embodiments, the remote plasma source is provided with an RF power source that generates from at least 0.1 kW to at most 10 kW of power, or of at least 0.2 kW to at most 5 kW of power, or of at least 0.5 to at most 2 kW of power.

In some embodiments, the reaction chamber is maintained at a pressure of at least 1 Pa to at most 1000 Pa, or at a pressure of at least 2 Pa to at most 500 Pa, or at a pressure of at least 5 Pa to at most 200 Pa, or at a pressure of at least 10 Pa to at most 100 Pa, while exposing the substrate to the active species.

In some embodiments, the substrate is maintained at a temperature of at least −25° C. to at most 400° C., or at a temperature of at least 0° C. to at most 200° C., or at a temperature of at least 25° C. to at most 150° C., or at a temperature of at least 50° C. to at most 100° C. while exposing the substrate to the active species.

In some embodiments, the substrate is exposed to the active species for a duration of at least 0.1 s to at most 1000 s, or of at least 0.2 s to at most 500 s, or of at least 0.5 s to at most 200 s, or of at least 1.0 s to at most 100 s, or of at least 2 s to at most 50 s, or of at least 5 s to at most 20 s.

Depositing the convertible layer may comprise executing a cyclical deposition process. The cyclical deposition process can include cyclical CVD, ALD, or a hybrid cyclical CVD/ALD process. For example, in some embodiments, the growth rate of a particular ALD process may be low compared to a CVD process. One approach to increase the growth rate may be that of operating at a higher deposition temperature than that typically employed in an ALD process, resulting in some portion of a chemical vapor deposition process, i.e. of at least one of non-self-limiting surface and gas phase reactions, but still taking advantage of the sequential introduction of reactants. Such a process may be referred to as cyclical CVD. In some embodiments, a cyclical CVD process may comprise the introduction of two or more precursors or reactants into the reaction chamber, wherein there may be a time period of overlap between the two or more precursors or reactants in the reaction chamber resulting in both an ALD component of the deposition and a CVD component of the deposition. This is referred to as a hybrid process. In accordance with further examples, a cyclical deposition process may comprise a continuous flow of one reactant or precursor and periodic pulsing of a second reactant or precursor into the reaction chamber.

In some embodiments, the convertible layer comprises a group IIIA element. Suitable group IIIA elements include B, Al, Ga, and In.

In some embodiments, the convertible layer comprises a group IVA element. Suitable group IVA elements include C, Si, Ge, and Sn.

In some embodiments, the convertible layer comprises a group VA element. Suitable group VA elements include N, P, As, and Sb.

In some embodiments, the convertible layer comprises a group VIA element. Suitable group VIA elements include O, S, Se, and Te.

In some embodiments, the convertible layer comprises a transition metal. Suitable transition metals include Sc, Ti, V, Cr, Mn, Fe, Co, Ni, Cu, Zn, Y, Zr, Nb, Mo, Tc, Ru, Rh, Cd, Hf, Ta, W, and Re.

In some embodiments, the convertible layer comprises a rare earth element. Suitable rare earth elements include lanthanides such as La, Ce, Pr, Nd, Pm, Sm, Eu, Gd, Tb, Dy, Ho, Er, Tm, Yb, and Lu.

In some embodiments, the convertible layer comprises an elemental metal, e.g. an elemental metal having an impurity content of less than 10 atomic percent, of less than 5 atomic percent, of less than 2 atomic percent, or less than 1 atomic percent.

In some embodiments, the convertible layer comprises a metal alloy.

In some embodiments, the convertible layer comprises a metal oxide.

In some embodiments, the convertible layer comprises a metal nitride.

In accordance with some examples of the disclosure, depositing the convertible layer comprises a thermal deposition process. In these cases, the deposition process does not include generating a plasma to form activated species for use in the deposition process.

In some embodiments, depositing a convertible layer on the substrate comprises executing a plurality of convertible layer deposition cycles. Thus, a convertible layer having a desired thickness can be formed on the substrate. A convertible layer deposition cycle comprises a convertible layer precursor pulse and a convertible layer reactant pulse. The convertible layer precursor pulse comprises exposing the substrate to a convertible layer precursor. The convertible layer reactant pulse comprises exposing the substrate to a convertible layer reactant.

In particular, deposing a convertible layer can comprise performing a specific number of deposition cycles before exposing the substrate to an active species. Thus, a pre-determined amount of convertible layer can be deposited on the substrate before the convertible layer is exposed to the active species. It shall be understood that the exact number of convertible layer deposition cycles that are performed until the substrate is exposed to the active species, can depend on the specific material that is deposited. In some embodiments, the method comprises executing from at least 2 convertible layer deposition cycles to at most 100 convertible layer deposition cycles for every exposure to an active species. In some embodiments, the method comprises executing from at least 5 convertible layer deposition cycles to at most 50 convertible layer deposition cycles for every active species exposure. In some embodiments, the method comprises executing from at least 10 convertible layer deposition cycles to at most 20 convertible layer deposition cycles for every active species exposure.

In some embodiments, the convertible layer precursor pulse lasts from at least 0.01 s to at most 100 s, or from at least 0.1 s to at most 10 s, or from at least 0.2 s to at most 5.0 s, or from at least 0.5 s to at most 2.0 s.

In some embodiments, the convertible layer reactant pulse lasts from at least 0.01 s to at most 100 s, or from at least 0.1 s to at most 10 s, or from at least 0.2 s to at most 5.0 s, or from at least 0.5 s to at most 2.0 s.

In some embodiments, subsequent convertible layer deposition cycles are separated by an inter convertible layer deposition cycle purge. In some embodiments, the duration of the inter convertible layer deposition cycle purge is from at least 0.01 s to at most 100 s, or from at least 0.1 s to at most 10 s, or from at least 0.2 s to at most 5.0 s, or from at least 0.5 s to at most 2.0 s.

In some embodiments, the convertible layer precursor pulse and the convertible layer reactant pulse are separated by an intra convertible layer deposition cycle purge. In some embodiments, the duration of the intra convertible layer deposition cycle purge is from at least 0.025 s to at most 2.0 s, or from at least 0.05 s to at most 0.8 s, or from at least 0.1 s to at most 0.4 s, or from at least 0.2 s to at most 0.3 s.

In some embodiments, the convertible layer comprises a metal oxide. The metal oxide comprising a metal and oxygen. In such embodiments, depositing the metal oxide on the substrate can comprise one or more metal oxide deposition sub cycles. A metal oxide deposition sub cycle comprises a metal precursor pulse and an oxygen reactant pulse. The metal precursor pulse comprises exposing the substrate to a metal precursor. The metal precursor comprises the metal. The oxygen reactant pulse comprises exposing the substrate to an oxygen reactant. The oxygen reactant comprises oxygen. Suitable oxygen reactants comprise oxygen-comprising gasses or compounds such as O₂, H₂O, O₃, and H₂O₂. In some embodiments, the oxygen reactant comprises H₂O.

In some embodiments, the metal oxide comprises titanium oxide.

In some embodiments, the convertible layer comprises a metal nitride. In some embodiments, the metal nitride comprises a transition metal nitride. Additionally or alternatively, the metal nitride comprises a rare earth metal nitride. In some embodiments, the metal nitride comprises vanadium nitride. In some embodiments, the metal nitride comprises titanium nitride. In such embodiments, depositing the metal nitride on the substrate can comprise one or more metal nitride deposition sub cycles. A metal nitride deposition sub cycle comprises a metal precursor pulse and a nitrogen reactant pulse. The metal precursor pulse comprises exposing the substrate to a metal precursor. The metal precursor comprises the metal. The nitrogen reactant pulse comprises exposing the substrate to a nitrogen reactant. The nitrogen reactant comprises nitrogen.

In some embodiments, the metal content of a convertible layer is from at least 1.0 atomic percent to at most 100.0 atomic percent, or from at least 3.0 atomic percent to at most 97.0 atomic percent, or from at least 5.0 atomic percent to at most 95.0 atomic percent, or from at least 10.0 atomic percent to at most 90.0 atomic percent, or from at least 20.0 atomic percent to at most 80.0 atomic percent, or from at least 30.0 atomic percent to at most 70.0 atomic percent, or from at least 40.0 atomic percent to at most 60.0 atomic percent.

In some embodiments, the nitrogen content of a convertible layer is from at least 1.0 atomic percent to at most 99.0 atomic percent, or from at least 3.0 atomic percent to at most 97.0 atomic percent, or from at least 5.0 atomic percent to at most 95.0 atomic percent, or from at least 10.0 atomic percent to at most 90.0 atomic percent, or from at least 20.0 atomic percent to at most 80.0 atomic percent, or from at least 30.0 atomic percent to at most 70.0 atomic percent, or from at least 40.0 atomic percent to at most 60.0 atomic percent.

In some embodiments, the oxygen content of a convertible layer is from at least 1.0 atomic percent to at most 99.0 atomic percent, or from at least 3.0 atomic percent to at most 97.0 atomic percent, or from at least 5.0 atomic percent to at most 95.0 atomic percent, or from at least 10.0 atomic percent to at most 90.0 atomic percent, or from at least 20.0 atomic percent to at most 80.0 atomic percent, or from at least 30.0 atomic percent to at most 70.0 atomic percent, or from at least 40.0 atomic percent to at most 60.0 atomic percent.

The convertible layer can, in some embodiments, be uniformly deposited on the substrate. For example, the convertible layer's thickness can be constant within a margin of error of 20%, 10%, 5%, 1%, or 0.1% over the substrate's surface, regardless of whether the convertible layer is deposited on a substantially flat part of the substrate, or in a gap such as a recess, trench, via, or the like.

In some embodiments, depositing the convertible layer on the substrate is followed by a post convertible layer deposition purge. In some embodiments, the duration of the post convertible layer deposition purge is from at least 0.025 s to at most 2.0 s, or from at least 0.05 s to at most 0.8 s, or from at least 0.1 s to at most 0.4 s, or from at least 0.2 s to at most 0.3 s.

In some embodiments, the metal precursor is selected from a halide, an oxyhalide, and an organometallic compound.

In some embodiments, the metal precursor comprises a transition metal precursor. In some embodiments, the metal precursor comprises a rare earth metal precursor. In some embodiments, the metal precursor comprises a group IIIA metal precursor.

In some embodiments, the metal precursor comprises an alkylamine ligand. In some embodiments, the metal precursor comprises an alkoxide ligand. In some embodiments, the metal precursor comprises an unsubstituted or an alkyl-substituted cyclopentadienyl ligand. In some embodiments, the metal precursor comprises a metal-halide bond.

In some embodiments, the metal precursor comprises a titanium precursor. Suitable titanium precursors include halides and organometallic titanium compounds. In some embodiments, the metal precursor comprises a titanium beta-diketonate. In some embodiments, the titanium precursor is selected from tetrakis(dimethylamido)titanium, titanium(IV) isopropoxide, trimethoxy(pentamethylcyclopentadienyl)titanium(IV), and titanium tetrachloride.

In some embodiments, the titanium precursor comprises a titanium halide such as titanium chloride, titanium fluoride, titanium bromide, and titanium iodide.

After the gap has been partially filled with a gap filling fluid, and optionally after solidifying the gap filling fluid to form a solidified material in the gap, the method further comprises, in some embodiments, a step of converting the gap filling fluid, or the solidified material, to a converted material. In some embodiments, converting the gap filling fluid or the solidified material comprises exposing the substrate to a direct plasma. Suitable direct plasmas include direct oxygen plasmas. Thus, in some embodiments a method as described herein comprises exposing the substrate to a direct oxygen plasma. Suitably, the direct oxygen plasma employs a plasma gas comprising a gas selected from O₂, H₂O, H₂O₂, O₃, and CO₂. Thus, a converted material that comprises oxygen can be formed. In some embodiments, an oxide can be formed in such a way.

Other suitable direct plasmas include direct nitrogen plasmas. A direct nitrogen plasma refers to a plasma that is generated in the reaction chamber in which the substrate is positioned. Thus, in some embodiments, a method as described herein comprises exposing the substrate to a direct nitrogen plasma. Suitably, the direct nitrogen plasma employs a plasma gas comprising a gas selected from NH₃, N₂H₂, N₂, and gas mixtures comprising H₂ and N₂. Thus, a converted material that comprises nitrogen can be formed. The solidified material can be further processed, and can be further changed into another suitable material. Thus, in some embodiments, a method as described herein further comprises a step of converting the gap filling fluid or the solidified material into a converted material. For example, converting the gap filling fluid or the solidified material to a converted material can comprise a step of exposing the substrate to a direct plasma, such as a direct nitrogen plasma. In some embodiments, a nitride can be formed in such a way.

In some embodiments, converting the gap filling fluid to form a converted material can occur at least partially simultaneously with forming the gap filling fluid. For example, when a plasma employing a plasma gas that comprises both a halogen and a conversion reactant is used, then a gap filling fluid can be formed which is readily converted to form a converted material. Thus a plasma that employs a plasma gas that comprises a halogen and an oxygen reactant such as an oxygen-containing substance such as O₂ can be employed for filling a gap with an oxide. Or, a plasma that employs a plasma gas that comprises a halogen and a reducing agent such as a hydrogen-containing substance such as H₂ can be employed for filling a gap with a metal. Or, a plasma that employs a plasma gas that comprises a halogen and a nitridation agent such as a nitrogen-containing substance such as N₂ can be used for filling a gap with a nitride. Or, a plasma that employs a plasma gas that comprises a halogen and a carburization agent such as a carbon-containing substance such as an alkane such as CH₄ can be used for filling a gap with a carbide.

In some embodiments, a method as described herein comprises exposing the substrate to a reducing agent after at least a part of the convertible layer has been converted into a gap filling fluid, and before converting the gap filling fluid to a converted material. Suitable reducing agents include hydrogen-comprising gasses, hydrogen radicals, and direct hydrogen plasmas.

In some embodiments, converting the gap filling fluid or the solidified material comprises exposing the gap filling fluid or the converted material to a reduction step and to an oxidation step. In some embodiments, the reduction step precedes the oxidation step. Alternatively, the oxidation step can precede the reduction step. In some embodiments, the reduction step comprises exposing the substrate to a hydrogen plasma. In some embodiments, the oxidation step comprises exposing the substrate to an oxygen plasma.

In some embodiments, converting the gap filling fluid or the solidified material comprises exposing the gap filling fluid or the converted material to a reduction step and to a nitridation step. It shall be understood that a nitridation step refers to a step of converting a material into a nitride. In some embodiments, the reduction step precedes the nitridation step. Alternatively, the nitridation step can precede the reduction step. In some embodiments, the reduction step comprises exposing the substrate to a hydrogen plasma. In some embodiments, the nitridation step comprises exposing the substrate to a nitrogen plasma. Suitable nitrogen plasmas include plasmas in which the plasma gas comprises at least one of N₂, NH₃, and N₂H₂.

In some embodiments, a method as described herein comprises a plurality of redeposition cycles. For example, a method as described herein can comprise from at least 2 to at most 5, or from at least 5 to at most 10, or from at least 10 to at most 20, or from at least 20 to at most 50, or from at least 50 to at most 100 redeposition cycles. A redeposition cycle comprises the steps of depositing a convertible layer on the substrate, exposing the substrate to active species, condensing the volatilized vapor, and solidifying the gap filling fluid to form a solidified material. Optionally, one or more subsequent steps in a redeposition cycle are separated by an intra deposition cycle purge. Optionally, subsequent redeposition cycles are separated by an inter deposition cycle purge.

In some embodiments, a method as described herein comprises a plurality of conversion cycles. For example, a method as described herein can comprise from at least 2 to at most 5, or from at least 5 to at most 10, or from at least 10 to at most 20, or from at least 20 to at most 50, or from at least 50 to at most 100 conversion cycles. A conversion cycle comprises exposing the substrate to the active species; optionally condensing the volatilized vapor; optionally solidifying the gap filling fluid; and, converting the gap filling fluid or the solidified material into a converted material. Optionally, one or more subsequent steps in a conversion cycle are separated by an intra conversion cycle purge. Optionally, subsequent conversion cycles are separated by an inter conversion cycle purge.

In some embodiments, a method as described herein comprises a plurality of super cycles. For example, a method as described herein can comprise from at least 2 to at most 5, or from at least 5 to at most 10, or from at least 10 to at most 20, or from at least 20 to at most 50, or from at least 50 to at most 100 super cycles. A super cycle comprises depositing a convertible layer on the substrate; exposing the substrate to the active species; optionally condensing the volatilized vapor; optionally solidifying the gap filling fluid; and, converting the gap filling fluid or the solidified material into a converted material.

Efficient formation of converted materials can occur when the present methods comprise alternatingly depositing convertible layers on the one hand, exposing the substrate to the active species, optionally condensing a volatilized vapor, optionally solidifying a gap filling fluid, converting the gap filling fluid or the solidified material to a converted material, and repeating the sequence.

The total number of super cycles comprised in a method as described herein depends, inter alia, on the total layer thickness that is desired. In some embodiments, the method comprises from at least 1 super cycle to at most 100 super cycles, or from at least 2 super cycles to at most 80 super cycles, or from at least 3 super cycles to at most 70 super cycles, or from at least 4 super cycles to at most 60 super cycles, or from at least 5 super cycles to at most 50 super cycles, or from at least 10 super cycles to at most 40 super cycles, or from at least 20 super cycles to at most 30 super cycles. In some embodiments, the method comprises at most 100 super cycles, or at most 90 super cycles, or at most 80 super cycles, or at most 70 super cycles, or at most 60 super cycles, or at most 50 super cycles, or at most 40 super cycles, or at most 30 super cycles, or at most 20 super cycles, or at most 10 super cycles, or at most 5 super cycles, or at most 4 super cycles, or at most 3 super cycles, or at most 2 super cycles, or a single super cycle.

It shall be understood that providing purge steps between different method steps suitably allows minimizing parasitic reactions between different precursors and reactants. It shall be understood that no plasma is generated in the reaction chamber during the purges.

In some embodiments, the convertible layer and the gap filling fluid comprise molybdenum (Mo), such as molybdenum deposited by means of physical vapor deposition. The convertible layer can be exposed to chlorine radicals that were created in an indirect or remote plasma to form a molybdenum-containing gap filling fluid. A molybdenum-containing gap filling fluid can be converted into a converted material using, for example, a hydrogen plasma to yield a gap that is at least partially filled with metallic molybdenum. A hydrogen plasma can employ pure hydrogen as a plasma gas. Alternatively, a hydrogen plasma can employ a mixture of hydrogen and argon as a plasma gas.

In some embodiments, the convertible layer comprises molybdenum oxide. Such a convertible layer can be exposed to a remote plasma in which the plasma gas comprises HCl to form a molybdenum-containing gap filling fluid. The molybdenum-containing gap filling fluid can then be subjected to a thermal anneal in an oxidizing agent such as H₂O₂ to yield a gap that is at least partially filled with molybdenum oxide.

In some embodiments, the convertible layer comprises molybdenum nitride. Such a convertible layer can be exposed to a remote plasma in which the plasma gas comprises Cl₂ to form a molybdenum-containing gap filling fluid. The molybdenum-containing gap filling fluid can then be exposed to a direct nitrogen plasma to yield a gap that is at least partially filled with molybdenum nitride.

In some embodiments, the convertible layer comprises molybdenum nitride. Such a convertible layer can be exposed to a remote plasma in which the plasma gas comprises N₂ and Cl₂. Thus, a molybdenum-containing gap filling fluid can be formed which is subsequently converted to molybdenum nitride in the same process step. Thus, it shall be understood that in some embodiments, forming the gap filling fluid and converting the gap filling fluid to form a converted material can occur in the same process step, and can occur simultaneously.

It shall be understood that techniques for forming convertible layers such as convertible layers comprising molybdenum are, as such, known in the art.

Exemplary gaps include recesses, contact holes, vias, trenches, and the like. In some embodiments, the gap has a depth of at least 5 nm to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap has a width of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap has a length of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the convertible layer is deposited at a substrate temperature of less than 800° C., or of at least 50° C. to at most 500° C., or of at least 100° C. to at most 300° C. In some embodiments, the convertible layer is deposited at a temperature of at least −25° C. to at most 300° C., or at a temperature of at least 0° C. to at most 250° C., or at a temperature of at least 25° C. to at most 200° C., or at a temperature of at least 50° C. to at most 150° C., or at a temperature of at least 75° C. to at most 125° C.

In some embodiments, and while the substrate is exposed to active species, the substrate is maintained at a temperature of less than 800° C., or of at least −25° C. to at most 800° C., or of at least 0 ° C. to at most 700° C., or of at least 25° C. to at most 600° C., or of at least 50° C. to at most 400° C., or of at least 75° C. to at most 200° C., or of at least 100° C. to at most 150° C.

In some embodiments, and while the gap filling fluid or the solidified material is converted into a converted material, the substrate is maintained at a temperature of less than 800° C., or of at least −25° C. to at most 800° C., or of at least 0 ° C. to at most 700° C., or of at least 25° C. to at most 600° C., or of at least 50° C. to at most 400° C., or of at least 75° C. to at most 200° C., or of at least 100° C. to at most 150° C. In some embodiments, the temperature at which the substrate is maintained while the substrate is exposed to active species equals the temperature at which the substrate is maintained while the gap filling fluid or the solidified material is converted into a converted material. In some embodiments, the temperature at which the substrate is maintained while the convertible layer is deposited equals at least one of the temperature at which the substrate is maintained while the substrate is exposed to the active species, and the temperature at which the gap filling fluid or the solidified material is converted into a converted material.

In some embodiments, at least one of condensing the volatilized vapor and solidifying the gap filling fluid is carried out at the same temperature at which the substrate is exposed to the active species. In some embodiments, converting the gap filling fluid or the solidified material into a converted material is done at the same temperature at which the substrate is exposed to the active species.

In some embodiments, the presently described methods are carried out at a pressure of less than 760 Torr or of at least 0.2 Torr to at most 760 Torr, of at least 1 Torr to at most 100 Torr, or of at least 1 Torr to at most 10 Torr. In some embodiments, the convertible layer is deposited at a pressure of at mot 10.0 Torr, or at a pressure of at most 5.0 Torr, or at a pressure of at most 3.0 Torr, or at a pressure of at most 2.0 Torr, or at a pressure of at most 1.0 Torr, or at a pressure of at most 0.1 Torr, or at a pressure of at most 10⁻² Torr, or at a pressure of at most 10⁻³ Torr, or at a pressure of at most 10⁻⁴ Torr, or at a pressure of at most 10−5 Torr, or at a pressure of at least 0.1 Torr to at most 10 Torr, or at a pressure of at least 0.2 Torr to at most 5 Torr, or at a pressure of at least 0.5 Torr to at most 2.0 Torr. In some embodiments, at least one of condensing the volatilized vapor and solidifying the gap filling fluid is carried out at the same pressure at which the convertible layer is deposited. In some embodiments, converting the gap filling fluid or the solidified material into a converted material is done at the same pressure at which the substrate is exposed to the active species.

In some embodiments, the method further comprises a step of curing the gap filling fluid or solidified material. In some embodiments, curing can be performed after all of the gap filling fluid or solidified material has been deposited. Alternatively, curing can be done cyclically. For example, a method as described herein can comprise a curing step after each step of exposing the substrate to an active species. Alternatively, a method as described herein can comprise a curing step after every other step of exposing the substrate to the active species. Alternatively, a method as described herein can comprise a curing step after from at least 1% to at most 2%, or from at least 2% to at most 5%, or from at least 5% to at most 10%, or from at least 10% to at most 20%, or from at least 20% to at most 50%, or from at least 50% to at most 100 of the steps of condensing the volatilized vapor.

A curing step suitably comprises subjecting the substrate to a form of energy, e.g. at least one of heat energy, radiation, and particles. Exemplary curing steps comprise exposing the substrate to UV radiation. Additionally or alternatively, a curing step can comprise exposing the substrate to a direct plasma, e.g. a noble gas plasma such as an argon plasma. Additionally or alternatively, a curing step can comprise exposing the substrate to one or more reactive species such as ions and/or radicals generated in a remote plasma, e.g. a remote noble gas plasma, such as a remote argon plasma. Additionally or alternatively, a curing step can comprise exposing the substrate to photons, e.g. at least one of UV photons, photons in the visible spectrum, IR photons, and photons in the microwave spectrum. Additionally or alternatively, a curing step can comprise heating the substrate.

A monocrystalline silicon wafer may be a suitable substrate. Other substrates may be suitable well, e.g. monocrystalline germanium wafers, gallium arsenide wafers, quartz, sapphire, glass, steel, aluminum, silicon-on-insulator substrates, plastics, etc.

In some embodiments, the convertible layer comprises an element selected from Ge, Sb, and Te.

Suitably, when the convertible layer comprises Ge, the active species can contain fluorine. For example, the active species can contain at least one of fluorine radicals and fluorine ions. Thus, a gap filling fluid comprising at least one of GeF₂ and GeF₄ can be formed.

Suitably, when the convertible layer comprises Sb, the active species can contain fluorine. For example, the active species can contain at least one of fluorine radicals and fluorine ions. Thus, a gap filling fluid comprising at least one of SbF₃ and SbF₅ can be formed.

Suitably, when the convertible layer comprises Te, the active species can contain bromine. For example, the active species can contain at least one of bromine radicals and bromine ions. Thus, a gap filling fluid comprising Te₂Br can be formed.

In some embodiments, the convertible layer can comprise an element selected from Nb, Ta, V, Ti, Zr, and Hf.

In some embodiments, the convertible layer can comprise niobium (Nb). In such embodiments, the active species can suitably comprise at least one of chlorine and iodine. For example, the active species can contain at least one of chlorine radicals, chlorine ions, iodine radicals, and iodine ions. Accordingly, a gap filling fluid comprising at least one of NbCl₄ and NbI₅ can be formed.

In some embodiments, the convertible layer can comprise tantalum (Ta). In such embodiments, the active species can suitably comprise one or more of fluorine, chlorine, bromine, and iodine. For example, the active species can comprise fluorine, chlorine, bromine, or iodine-comprising radicals or ions. Accordingly, a gap filling fluid comprising at least one of TaCl₅, TaI₅, TaF₅, and TaBr₅ can be formed.

In some embodiments, the convertible layer can comprise vanadium (V). In such embodiments, the active species can suitably comprise at least one of fluorine and bromine. For example, the active species can comprise fluorine or bromine-comprising ions or radicals. Accordingly, a gap filling fluid comprising at least one of VF₄, VF₅, VBr₃ can be formed.

In some embodiments, the convertible layer can comprise V and O. In such embodiments, the active species can suitably comprise at least one of F and Cl. For example, the active species can contain at least one of chlorine ions, chlorine radicals, fluorine ions, and fluorine radicals. Accordingly, a gap filling fluid comprising vanadium, oxygen, and a one of fluorine and chlorine can be obtained. Examples of such gap filling fluids include VOCl₂, V₂O₂F₄, VOCl₃, and VOF₃.

In some embodiments, the convertible layer can comprise titanium (Ti). In such embodiments, the active species can suitably comprise fluorine. For example, the active species can contain at least one of fluorine ions and radicals. Accordingly, a gap filling fluid comprising TiF₄ can be formed.

In some embodiments, the convertible layer can comprise zirconium (Zr). In such embodiments, the active species can suitably comprise one of chlorine, bromine, and iodine. For example, the active species can contain one or more of ions and radicals comprising at least one of chlorine, bromine, and iodine. Accordingly, a gap filling fluid comprising at least one of ZrI₄, ZrCl₄, and ZrBr₄ can be formed.

In some embodiments, the convertible layer can comprise Zr, and O. In such embodiments, the active species suitably comprises H and F. For example, the active species can contain at least one of H and F ions and H and F radicals. In such embodiments, a gap filling fluid comprising ZrF₆(H₂O)₂ can be obtained.

In some embodiments, the convertible layer can comprise hafnium (Hf). In such embodiments, the active species can suitably comprise one of chlorine and iodine. For example, the active species can comprise at least one of chlorine radicals, chlorine ions, iodine radicals, and iodine ions. Accordingly, a gap filling fluid comprising at least one of HfCl₄ and HfI₄ can be formed.

In some embodiments, the convertible layer can comprise rhodium (Rh). In such embodiments, the active species can suitably comprise bromine. For example, the active species can contain at least one of bromine-comprising atoms and radicals. Accordingly, a gap filling fluid comprising RhBr₃ can be formed.

In some embodiments, the convertible layer can comprise iron (Fe). In such embodiments, the active species can suitably comprise bromine. For example, the active species can contain at least one of bromine-comprising atoms and radicals. Accordingly, a gap filling fluid comprising at least one of FeBr₃ and FeBr₂ can be formed.

In some embodiments, the convertible layer can comprise chromium (Cr). In such embodiments, the active species can suitably comprise fluorine. For example, the active species can contain at least one of fluorine-comprising atoms and radicals. Accordingly, a gap filling fluid comprising CrF₅ can be formed.

In some embodiments, the convertible layer can comprise molybdenum (Mo). In such embodiments, the active species can suitably comprise at least one of chlorine, bromine, or iodine. For example, the active species can contain at least one of chlorine, bromine, or iodine-comprising atoms and radicals. Accordingly, a gap filling fluid comprising at least one of Mo₆Cl₁₂, MoCl₄, MoI₃, and MoBr₃ can be formed.

In some embodiments, the convertible layer comprises gold (Au). In such embodiments, the active species can suitably comprise fluorine or bromine. For example, the active species can contain at least one of fluorine or bromine-comprising atoms and radicals. Accordingly, a gap filling fluid comprising at least one of AuF₃ and AuBr can be formed.

In some embodiments, the convertible layer comprises silver (Ag). In such embodiments, the active species can suitably comprise fluorine. For example, the active species can contain at least one of fluorine-comprising atoms and radicals. Accordingly, a gap filling fluid comprising AgF₃ can be formed.

In some embodiments, the convertible layer comprises platinum (Pt). In such embodiments, the active species can suitably comprise bromine. For example, the active species can contain at least one of bromine-comprising atoms and radicals. Accordingly, a gap filling fluid comprising PtBr₄ can be formed.

In some embodiments, the convertible layer comprises nickel (Ni). In such embodiments, the active species can suitably comprise bromine. For example, the active species can contain at least one of bromine-comprising atoms and radicals. Accordingly, a gap filling fluid comprising NiBr₂ can be formed.

In some embodiments, the convertible layer comprises copper (Cu). In such embodiments, the active species can suitably comprise bromine. For example, the active species can contain at least one of bromine-comprising atoms and radicals. Accordingly, a gap filling fluid comprising CuBr₂ can be formed.

In some embodiments, the convertible layer comprises cobalt (Co). In such embodiments, the active species can suitably comprise iodine. For example, the active species can contain at least one of iodine-comprising atoms and radicals. Accordingly, a gap filling fluid comprising CoI can be formed.

In some embodiments, the convertible layer can comprise Co and O, and the active species comprises H and Cl comprising radicals or ions. In such embodiments, a gap filling fluid comprising CoCl₂(H₂O)₂ can be formed.

In some embodiments, the convertible layer comprises zinc (Zn), for example metallic Zn or an inorganic Zn compound. In such embodiments, the active species can suitably comprise at least one of chlorine or iodine radicals and ions. Accordingly, a gap filling fluid comprising at least one of ZnCl₂ and ZnI₂ can be formed.

In some embodiments, the convertible layer can comprise aluminum (Al). In such embodiments, the active species can suitably comprise at least one of chlorine and iodine comprising radicals or ions. Accordingly, a gap filling fluid comprising at least one of AlCl₃ and AlI₃ can be formed.

In some embodiments, the convertible layer can comprise indium (In). In such embodiments, the active species can suitably comprise at least one of radicals and ions comprising bromine. Accordingly, a gap filling fluid comprising InBr₃ can be formed.

In some embodiments, the convertible layer comprises tin (Sn). In such embodiments, the active species can suitably comprise at least one ions and radicals comprising chlorine and bromine. Accordingly, a gap filling fluid comprising at least one of SnCl₂ and SnBr₂ can be formed.

In some embodiments, the convertible layer can comprise bismuth (Bi). In such embodiments, the active species can suitably comprise at least one of atoms and radicals comprising fluorine. Accordingly, a gap filling fluid comprising BiF₅ can be formed.

In accordance with yet additional embodiments of the disclosure, a device or portion thereof can be formed using a method and/or a structure as described herein. The device can include a substrate, one or more insulating layers, one or more metallic layers, and one or more semiconducting layers. The device further comprises a gap filled according to a method as disclosed herein.

Further described is a field effect transistor comprising a gate contact comprising a layer formed according to a method as described herein.

Further described is a metal contact comprising a layer deposited by means of a method as described herein.

Further provided herein is a metal-insulator-metal (MIM) metal electrode comprising a layer formed by means of a method as described herein.

Further described herein is a system that comprises a reaction chamber, a precursor gas source, a deposition reactant gas source, an active species source, a conversion reactant source, and a controller. The precursor gas source comprises a metal precursor. The deposition reactant gas source comprises a deposition reactant. The active species source is arranged for providing an active species. The conversion reactant source is arranged for providing a conversion reactant. The controller is configured to control gas flow into the reaction chamber to form a layer on a substrate by means of a method as described herein.

In some embodiments, the system comprises two distinct, i.e. separate, reaction chambers: a first reaction chamber and a second reaction chamber. The first reaction chamber is configured for depositing a convertible layer. The second reaction chamber is configured for exposing the substrate to an active species, for converting a gap filling fluid or a solidified material into a converted material, or both. In some embodiments, the first reaction chamber is maintained at a first reaction chamber temperature, and the second reaction chamber is maintained at a second reaction chamber temperature. In some embodiments, the first reaction chamber temperature is lower than the second reaction chamber temperature, for example from at least 10° C. lower to at most 100° C. lower. In some embodiments, the first reaction chamber temperature is higher than the second reaction chamber temperature, for example from at least 10° C. higher to at most 100° C. higher. In some embodiments, the first reaction chamber temperature is equal to the second reaction chamber temperature, e.g. within a margin of 10° C., 20° C., 30° C., or 40° C.

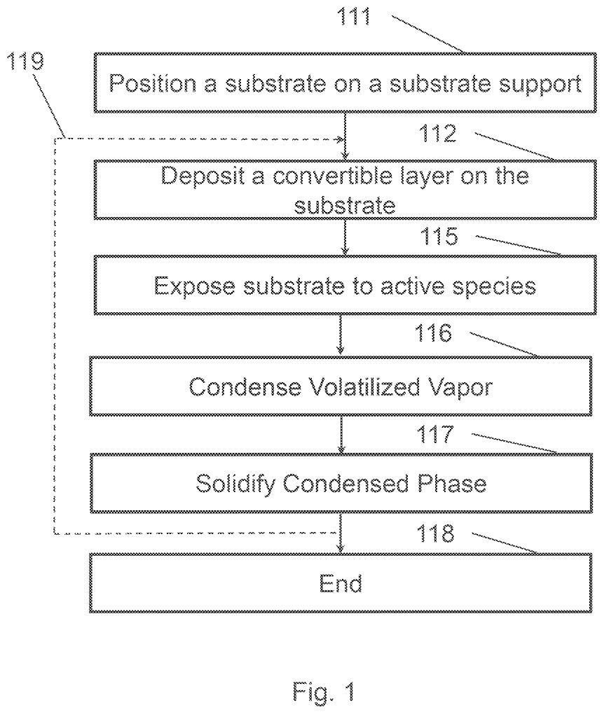

FIG. 1 shows a schematic representation of an embodiment of a method as described herein. The method can be used to fill a gap, for example, in order to form an electrode in a semiconductor device. However, unless otherwise noted, the presently described methods are not limited to such applications. The method comprises a step (111) of positioning a substrate on a substrate support. The substrate support is positioned in a reaction chamber. Suitable substrate supports include pedestals, susceptors, and the like. The method further comprises depositing a convertible layer on the substrate (112). The convertible layer comprises a volatilizable element. Optionally, the reaction chamber is then purged. Then, the method comprises exposing the substrate to an active species (115). As a result, the volatilizable element is volatilized and a volatilized vapor is formed. Without the invention being bound by any particular theory or mode of operation, it is believed that under the right conditions, that a skilled artisan can determine based on the present disclosure, the vapor pressure of the volatilized vapor in a gap is sufficiently big for the volatilized vapor to condense in the gap, and to form a flowable phase. Accordingly, the volatilized vapor is condensed in the gap (116), to form a gap filling fluid in the gap. The gap filling fluid can then be solidified (117), e.g. by cooling down the substrate, or by another means, such as by exposing the substrate to radiation. Optionally, the steps of depositing a convertible layer on the substrate (112), exposing the substrate to active species (115), condensing the volatilized vapor (116), and solidifying the gap filling fluid (117) can be repeated (119) one or more times. Thus, a gap can be efficiently filled. When the gap has been filled to a desired extent, the method ends (118).

Optionally, a purge is carried out after depositing a convertible layer on the substrate (112) by means of a post-deposition purge. It shall be understood that purging may partially or wholly overlap with the steps of condensing volatilized vapor and solidifying gap filling fluid. Optionally, a purge is carried out after exposing the substrate to an active species (115). Purging can be done by exposing the substrate to a purge gas that, in turn, can be done, for example, by providing a purge gas to the reaction chamber. Exemplary purge gasses include noble gasses. Exemplary noble gasses include He, Ne, Ar, Xe, and Kr. Alternatively, the purging can comprise transporting the substrate through a purge gas curtain. During a purge, surplus chemicals and reaction byproducts, if any, can be removed from the substrate surface or reaction chamber, such as by purging the reaction space or by moving the substrate, before the substrate is subjected to a next step.

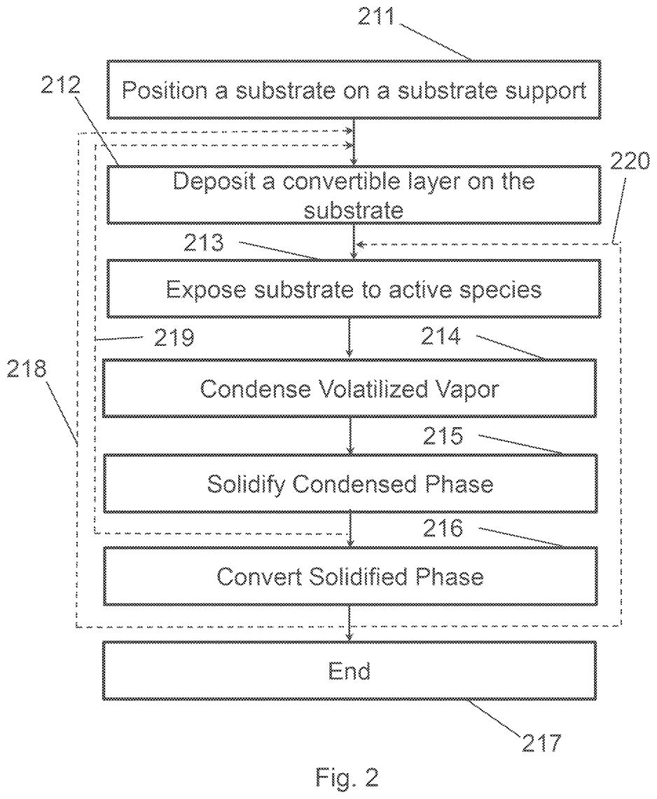

FIG. 2 schematically shows another embodiment of a method as described herein. The method of FIG. 2 is similar to that of FIG. 1 in the sense that it also comprises positioning a substrate on a substrate support (211), depositing a convertible layer on the substrate (212), exposing the substrate to active species (213), condensing volatilized vapor (214), and solidifying the gap filling fluid (215). As before, the steps from depositing a convertible layer on the substrate (212) to solidifying gap filling fluid (215) can be repeated (219) one or more times.

The method of FIG. 2 differs from the method of FIG. 1 in that it further comprises a step of converting the solidified phase (216) to form a converted material. Optionally, a purge is carried out after the step of converting the solidified phase (216). The step of converting the solidified phase (216) can comprise, for example, exposing the substrate to a direct plasma such as a direct oxygen plasma or a direct nitrogen plasma. Optionally, the method of FIG. 2 comprises a plurality of super cycles in which the steps from depositing a convertible layer on the substrate (212) to converting the solidified phase (216) are repeated one or more times. By selecting a pre-determined amount of super cycles, a pre-determined amount of converted material can be formed on the substrate. Additionally or alternatively, the method of FIG. 2 can comprise a plurality of conversion cycles in which the steps of exposing the substrate to active species (213), condensing volatilized vapor (214), solidifying gap filling fluid (215), and converting solidified phase (216) are repeated (220) one or more times. Doing so can advantageously enhance throughput. After a pre-determined amount of converted material has been formed on the substrate, the method of FIG. 2 ends (217).

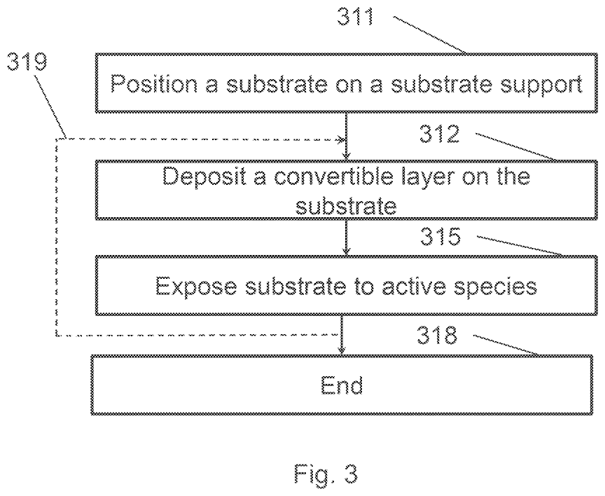

FIG. 3 shows a schematic representation of an embodiment of a method as described herein. The method can be used to fill a gap, for example, in order to form an electrode in a semiconductor device. However, unless otherwise noted, the presently described methods are not limited to such applications. The method comprises a step (311) of positioning a substrate on a substrate support. The substrate support is positioned in a reaction chamber. Suitable substrate supports include pedestals, susceptors, and the like. The method further comprises depositing a convertible layer on the substrate (312). Optionally, the reaction chamber is then purged. Then, the method comprises exposing the substrate to an active species (315). As a result, the convertible layer is converted into a gap filling fluid. Without the invention to be bound by any particular theory or mode of operation, it is believed that under the right conditions, that a skilled artisan can determine based on the present disclosure, the convertible layer forms a flowable phase when exposed to a pre-determined active species. Optionally, the steps of depositing a convertible layer on the substrate (312), and exposing the substrate to active species (315), can be repeated (319) one or more times. Thus, a gap can be efficiently filled. When the gap has been filled to a desired extent, the method ends (318).

Optionally, a purge is carried out after depositing a convertible layer on the substrate (312) by means of a post-deposition purge. Optionally, a purge is carried out after exposing the substrate to an active species (315).

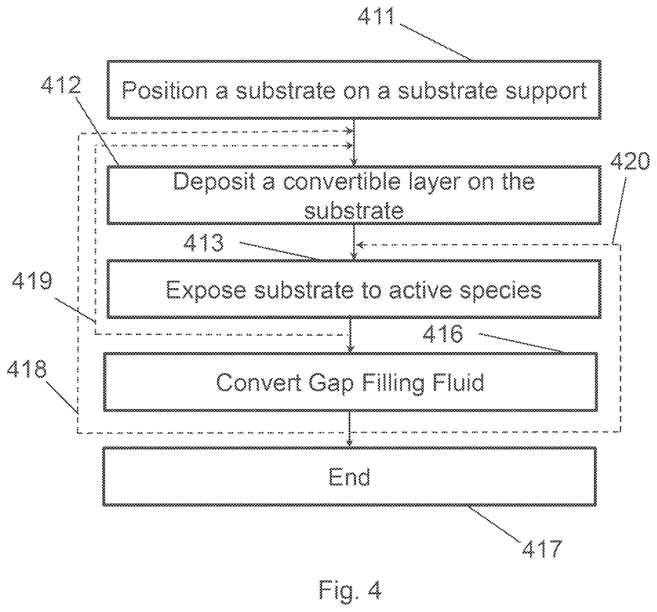

FIG. 4 schematically shows another embodiment of a method as described herein. The method of FIG. 4 is similar to that of FIG. 3 in the sense that it also comprises positioning a substrate on a substrate support (411), depositing a convertible layer on the substrate (412), and exposing the substrate to active species (413). As before, the steps of depositing a convertible layer on the substrate (412) and exposing the gap filling fluid to an active species (413) can be repeated (419) one or more times.

The method of FIG. 4 differs from the method of FIG. 3 in that it further comprises a step of converting the gap filling fluid (416) to form a converted material. Optionally, the step of converting the gap filling fluid (416) is carried out after the gap filling fluid has been solidified. Optionally, a purge is carried out after the step of converting the gap filling fluid (416). The step of converting the gap filling fluid (416) can comprise, for example, exposing the substrate to a direct plasma such as a direct oxygen plasma or a direct nitrogen plasma. Optionally, the method of FIG. 2 comprises a plurality of super cycles in which the steps from depositing a convertible layer on the substrate (412) to converting the gap filling fluid (416) are repeated one or more times. By selecting a pre-determined amount of super cycles, a pre-determined amount of converted material can be formed on the substrate. Additionally or alternatively, the method of FIG. 4 can comprise a plurality of conversion cycles in which the steps of exposing the substrate to active species (413) and converting the gap filling fluid (416) are repeated (420) one or more times. Doing so can advantageously enhance throughput. After a pre-determined amount of converted material has been formed on the substrate, the method of FIG. 4 ends (417).

In an exemplary embodiment of a method according to FIG. 4, the convertible layer comprises titanium oxide, exposing the substrate to active species comprises exposing the substrate to fluorine radicals, and converting the gap filling fluid comprises a reduction step and an oxidation step. In particular, the reduction step comprises exposing the substrate to a H₂ plasma, i.e. to a plasma that employs a plasma gas comprising H₂. The oxidation step comprises exposing the substrate to an O₂ plasma, i.e. to a plasma that employs a plasma gas comprising O₂.

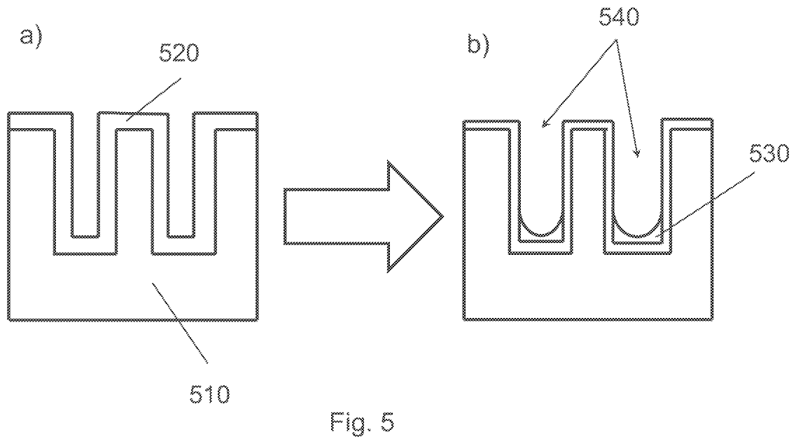

FIG. 5 illustrates the operation of a method as described herein. In particular, FIG. 5 shows a substrate (510) comprising a plurality of gaps (540). Panel a) shows a convertible layer (520) that is conformally deposited on the substrate (510). Panel b) shows the same substrate (510) after it has been exposed to an active species. The active species exposure can turn at least a part of the convertible layer (520) into a volatilized vapor that can be condensed to form a gap filling fluid in the gap. Optionally, the gap filling fluid can then be solidified to form a solidified material (530). In an alternative mode of operation, the active species exposure can result in direct formation of a liquid phase, without intermediate formation of a vapor. Optionally, the liquid phase can then be solidified to form a solidified material (530). Optionally, the solidified material (530) or gap filling fluid can be converted into a converted material, as described elsewhere herein.

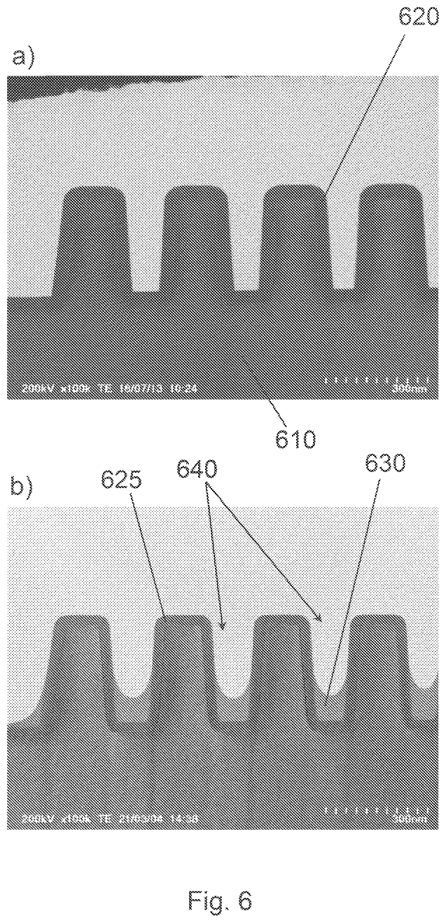

FIG. 6 panel a) shows a transmission electron microscopy (TEM) image of a substrate (610) on which a TiO₂ layer (620) is deposited. The TiO₂ layer (620) is an example of a convertible layer. FIG. 6 panel b) shows how a part of the TiO₂ layer is converted into a layer comprising titanium, oxygen, and fluorine (630) upon exposure to fluorine radicals. The layer comprising titanium, oxygen, and fluorine (630) partially fills gaps (640) provided in the substrate. Another part of the TiO₂ layer (625) is not converted. This other part of the TiO₂ layer (625) can be at least partially further converted into a layer comprising titanium, oxygen, and fluorine (630) upon further exposure to fluorine radicals.

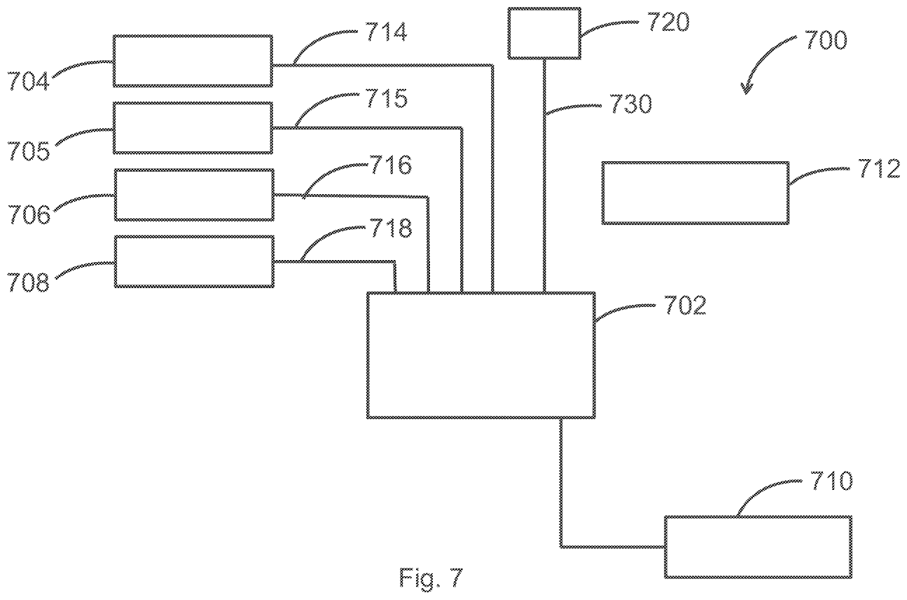

FIG. 7 illustrates a system (700) in accordance with yet additional exemplary embodiments of the disclosure. The system (700) can be used to perform a method as described herein and/or form a structure or device portion, e.g. in an integrated circuit, as described herein.

In the illustrated example, the system (700) includes one or more reaction chambers (702), a precursor gas source (704), a reactant gas source (706), a purge gas source (708), an exhaust (710), and a controller (712).

The reaction chamber (702) can include any suitable reaction chamber, such as an ALD or CVD reaction chamber. In some embodiments, the reaction chamber comprises a showerhead injector, a substrate support, and a direct plasma source (none of which are shown). In exemplary modes of operation, an RF bias can be applied to the showerhead injector by the direct plasma source, and the substrate support can be grounded. Thus, a substrate can be efficiently exposed to a direct plasma that can be useful, for example, when converting a gap filling fluid or a solidified material into a converted material.

The precursor gas source (704) can include a vessel and one or more precursors as described herein-alone or mixed with one or more carrier (e.g., noble) gases. The reactant gas source (706) can include a vessel and one or more reactants as described herein-alone or mixed with one or more carrier gases. The purge gas source (708) can include one or more inert gases as described herein. Although illustrated with four gas sources (704-708), the system (700) can include any suitable number of gas sources. The gas sources (704-708) can be coupled to reaction chamber (702) via lines (714-718), which can each include flow controllers, valves, heaters, and the like. The exhaust (710) can include one or more vacuum pumps.

The system (700) of FIG. 7 comprises a remote plasma source (720) that is operationally coupled to the reaction chamber (702). Suitable remote plasma sources (720) as such are known in the Art, and comprise inductively coupled plasma sources, microwave plasma sources, and capacitive plasma sources. A remote plasma source can be positioned adjacent to the reaction chamber, or the remote plasma source can be positioned at a certain distance from the reaction chamber, e.g. at a distance of at least 1.0 m to at most 10.0 m. When the remote plasma source (720) is positioned at a certain distance from the reaction chamber (702), the remote plasma source (720) can be operationally connected to the reaction chamber (702) via an active species duct (730). The active species duct can comprise a pipe. Optionally, the pipe can contain one or more mesh plates. The mesh plates can at least partially block some reactive species such as ions and electromagnetic radiation while letting other reactive species, e.g. radicals, pass.

The controller (712) includes electronic circuitry and software to selectively operate valves, manifolds, heaters, pumps and other components included in the system (700). Such circuitry and components operate to introduce precursors, reactants, and purge gases from the respective sources (704-708). The controller (712) can control timing of gas pulse sequences, temperature of the substrate and/or reaction chamber, pressure within the reaction chamber, and various other operations to provide proper operation of the system (700). The controller (712) can include control software to electrically or pneumatically control valves to control flow of precursors, reactants and purge gases into and out of the reaction chamber (702). The controller (712) can include modules such as a software or hardware component, e.g., a FPGA or ASIC, which performs certain tasks. A module can advantageously be configured to reside on the addressable storage medium of the control system and be configured to execute one or more processes.

Other configurations of the system (700) are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into the reaction chamber 502. Further, as a schematic representation of a system, many components have been omitted for simplicity of illustration, and such components may include, for example, various valves, manifolds, purifiers, heaters, containers, vents, and/or bypasses.

During operation of the system (700), substrates, such as semiconductor wafers (not illustrated), are transferred from, e.g., a substrate handling system to reaction chamber (702). Once such substrate(s) are transferred to reaction chamber (702), one or more gases from the gas sources (704-708), such as precursors, reactants, carrier gases, and/or purge gases, are introduced into the reaction chamber (702).

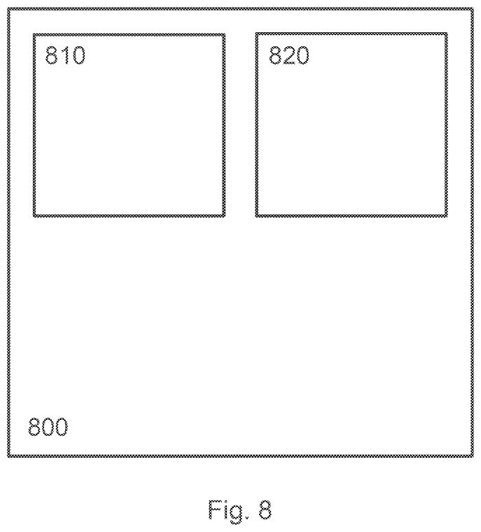

FIG. 8 shows another embodiment of a system (800) as described herein in a stylized way. The system (800) of FIG. 8 is similar to that of FIG. 7. It comprises two distinct reaction chambers: a first reaction chamber (810) and a second reaction chamber (820). The first reaction chamber (810) is arranged for depositing a convertible layer. The second reaction chamber (820) is arranged for at least one of exposing the substrate to an active species and converting a gap filling fluid or a solidified material into a converted material.

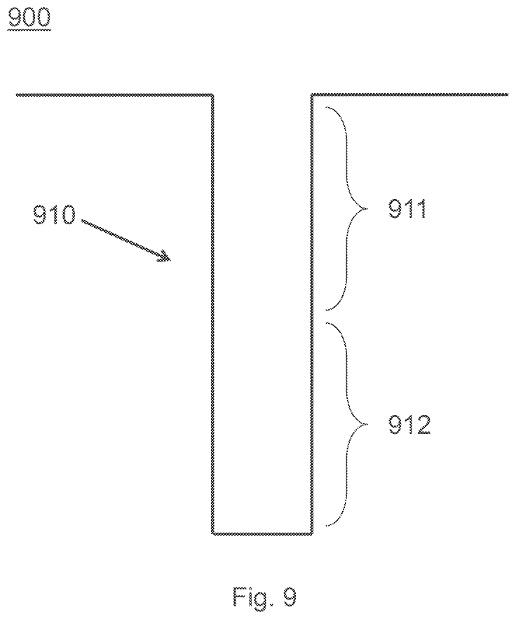

FIG. 9 shows a schematic representation of a substrate (900) comprising a gap (910). The gap (910) comprises a proximal part (911) and a distal part (912). The proximal part (911) comprises a proximal surface, and the distal part (912) comprises a distal surface. The present methods result in formation of at least one of a gap filling fluid, a solidified material, and a converted material on the distal surface compared to the proximal surface, thereby resulting in a bottom-up filling of the gap (910).

Further, an exemplary method for filling a gap according to an embodiment of a method as described herein is discussed. A convertible layer comprising TiO₂ is deposited on a substrate using a generic atomic layer deposition process, as is known in the Art. Then, the substrate is exposed to an active species comprising fluorine radicals. The active species is generated using a remote plasma source. The remote plasma source is provided with a plasma gas comprising NF₃ and Ar. In particular, NF₃ is provided to the remote plasma source at a flow rate of 2.8 sccm, and Ar is provided at a flow rate of 0.2 slm. The remote plasma is powered with a plasma power of 0.8 kW. While exposing the substrate to the active species, the substrate is positioned in a reaction chamber that is maintained at a pressure of 60 Pa, and the substrate is maintained at a temperature of at least 100° C. to at most 150° C. The substrate is exposed to the active species for at least 20 s to at most 40 s. It shall be noted that in this example, process conditions are given for a reaction chamber volume of 1 liter and for 300 mm wafers. The skilled person understands that these values can be readily extended to other reaction chamber volumes and wafer sizes.

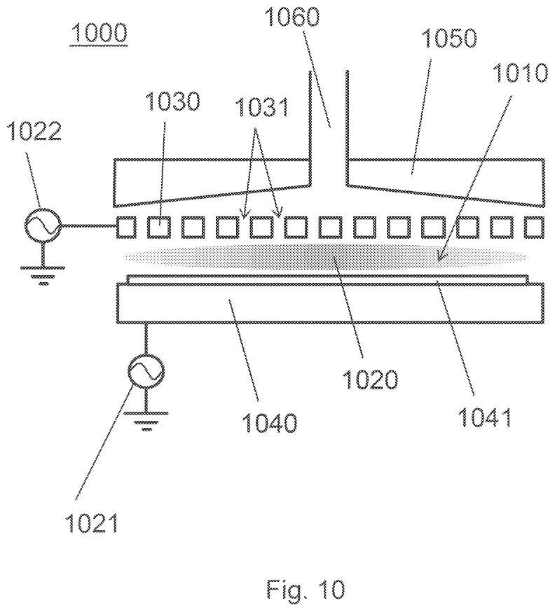

FIG. 10 shows a schematic representation of an embodiment of a system (1000) as described herein. The system (1000) comprises a reaction chamber (1010) in which a plasma (1020) is generated. In particular, the plasma (1020) is generated between a showerhead injector (1030) and a substrate support (1040).

In the configuration shown, the system (1000) comprises two alternating current (AC) power sources: a high frequency power source (1021) and a low frequency power source (1022). In the configuration shown, the high frequency power source (1021) supplies radio frequency (RF) power to the showerhead injector, and the low frequency power source (1022) supplies an alternating current signal to the substrate support (1040). The radio frequency power can be provided, for example, at a frequency of 13.56 MHz or higher, e.g. at a frequency of at least 20 MHz to at most 50 MHz, or at a frequency of at least 50 MHz to at most 100 MHz, or at a frequency of at least 100 MHz to at most 200 MHz, or at a frequency of at least 200 MHz to at most 500 MHz, or at a frequency of at least 500 MHz to at most 1000 MHz, or at a frequency of at least 1000 MHz to at most 2000 MHz, or at a frequency of at least 2000 MHz to at most 5000 MHz. The low frequency alternating current signal can be provided, for example, at a frequency of 2 MHz or lower, such as at a frequency of at least 100 kHz to at most 200 kHz, or at a frequency of at least 200 kHz to at most 500 kHz, or at a frequency of at least 500 kHz to at most 1000 kHz, or at a frequency of at least 1000 kHz to at most 2000 kHz.

Process gas comprising precursor, reactant, or both, is provided through a gas line (1060) to a conical gas distributor (1050). The process gas then passes through holes (1031) in the showerhead injector (1030) to the reaction chamber (1010).

Whereas the high frequency power source (1021) is shown as being electrically connected to the showerhead injector, and the low frequency power source (1022) is shown as being electrically connected to the substrate support (1040), other configurations are possible as well. For example, in some embodiments (not shown), both the high frequency power source and the low frequency power source can be electrically connected to the showerhead injector; or both the high frequency power source and the low frequency power source can be electrically connected to the substrate support; or the high frequency power source can be electrically connected to the substrate support, and the low frequency power source can be electrically connected to the showerhead injector.

A direct plasma system such as the system (1000) of FIG. 10 can, in some embodiments, be advantageously used for filling a gap with a titanium-containing material. For example, a substrate can be provided that contains a convertible layer containing titanium. The convertible layer can comprise any titanium-containing material, such as elemental titanium, titanium oxide, titanium carbide, titanium nitride, or mixtures thereof. The substrate can then be exposed to a fluorine-containing plasma, such as a plasma in which the plasma gas comprises a fluorocarbon such as a fluorinated alkane such as perfluoro-octane. Any fluorocarbon can be used, but liquid fluorocarbons such as perfluoro-octane are especially advantageous because of their ease of use. Thus, the convertible layer can be converted to form a titanium and fluorine-containing gap filling fluid. The fluorine-containing gap filling fluid can then be converted to form another titanium-containing material in the gap, such as elemental titanium, titanium oxide, titanium carbide, titanium nitride, or mixtures thereof. This can be done, for example, by exposing the substrate to a thermal, direct plasma, or remote plasma treatment using one or more of a noble gas, a reducing agent such as H₂, an oxidizing agent such as O₂, a nitridation agent such as NH₃, and a carburization agent such as CH₄.

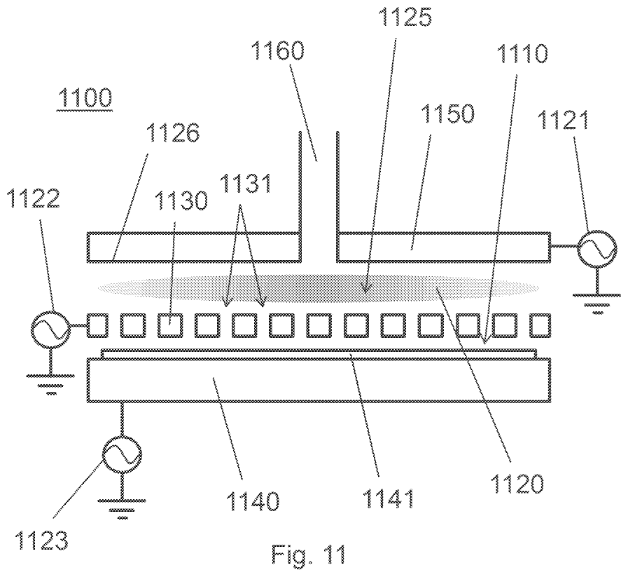

FIG. 11 shows a schematic representation of another embodiment of a system (1100) as described herein. The system (1100) comprises a reaction chamber (1110) which is separated from a plasma generation space (1125) in which a plasma (1120) is generated. In particular, the reaction chamber (1110) is separated from the plasma generation space (1125) by a showerhead injector (1130), and the plasma (1120) is generated between the showerhead injector (1130) and a plasma generation space ceiling (1126).

In the configuration shown, the system (1100) comprises three alternating current (AC) power sources: a first power source (1121), a second power source (1122), and a third power source (1123).

In some embodiments, the first power source (1121) is a high frequency power source, the second power source (1122) is a low frequency power source. In such embodiments, the first power source (1121) supplies radio frequency (RF) power to the plasma generation space ceiling, and the second power source (1122) supplies an alternating current signal to the showerhead injector (1130). Thus, a plasma can be generated in the plasma generation space (1125). In such embodiments, the third power source (1123) can be omitted, or can be turned off.

Alternatively, and in some embodiments, the first power source (1121) is a low frequency power source, the second power source (1122) is a high frequency power source, and the third power source (1123) is another low frequency power source. In such embodiments, the first power source (1121) supplies an alternating current signal to the plasma generation space ceiling, the second power source (1122) supplies RF power to the showerhead injector (1130), and the third power source (1123) supplies an alternating current signal to the substrate support (1140). In such embodiments, a plasma can be suitably generated both in the plasma generation space (1125) and in the reaction chamber (1130) between the substrate support (1140) and the showerhead injector (1130).

The radio frequency power can be provided, for example, at a frequency of 13.56 MHz or higher. The low frequency alternating current signal of the first and second low frequency power sources (1122,1123) can be provided, for example, at a frequency of 2 MHz or lower.

Process gas comprising precursor, reactant, or both, is provided through a gas line (1160) that passes through the plasma generation space ceiling (1126), to the plasma generation space (1125). Active species such as ions and radicals generated by the plasma (1125) from the process gas pass through holes (1131) in the showerhead injector (1130) to the reaction chamber (1110). Optionally, one or more of precursor and reactant can be directly provided to the reaction chamber (1130).

In some embodiments, a system (1100) as shown in FIG. 11 can be employed for converting a convertible layer, such as a titanium-containing convertible layer, into a gap filling fluid. For example, the convertible layer can contain at least one of titanium oxide, titanium nitride, and titanium oxynitride. For example, a fluorine-containing gas can be provided to the plasma generation space (1125) to form fluorine-containing radicals. For example, a fluorocarbon such as perfluoro-octane or CF₄ mixed with, for example, a noble gas such as Ar, can be used to generate at least one of F radicals and CFₓ radicals. It shall be understood that x can be an integer from at least 1 to at most 3. Alternatively, x can be a non-integer positive number, in which case the notation “CFₓ” can refer to a mixture of various carbon and fluorine-containing radicals. Such radicals are generated along with ions in the plasma generation space (1125). Suitably, a showerhead injector (1130) blocks ions and lets radicals pass. As an alternative to a showerhead injector (1130), a mesh plate can be employed. It shall be understood that mesh plates as such are known in the art.

In yet another alternative configuration, a mesh plate (not shown), such as a grounded mesh plate can be installed between a showerhead injector (1130) and a substrate support (1140). Thus, a plasma can be generated in the reaction chamber, between the mesh plate and the showerhead injector (1130), in which case no plasma need be generated in the plasma generation space (1125). Such a configuration can also advantageously block ions while letting radicals pass.

Thus, a substrate containing a convertible layer such as a convertible layer comprising at least one of titanium oxide, titanium nitride, and titanium oxynitride, can be exposed to radicals such as fluorine-containing radicals, such as the aforementioned F radicals and CFₓ radicals. Accordingly, a titanium and fluorine containing gap filling fluid can be formed. It shall be understood that various process parameters such as flow rates, plasma power, plasma frequency, and temperature, can be adapted in order to control the aforementioned fluorination process, e.g. by influencing the amount of CFₓ and F radicals that reach the substrate's surface.

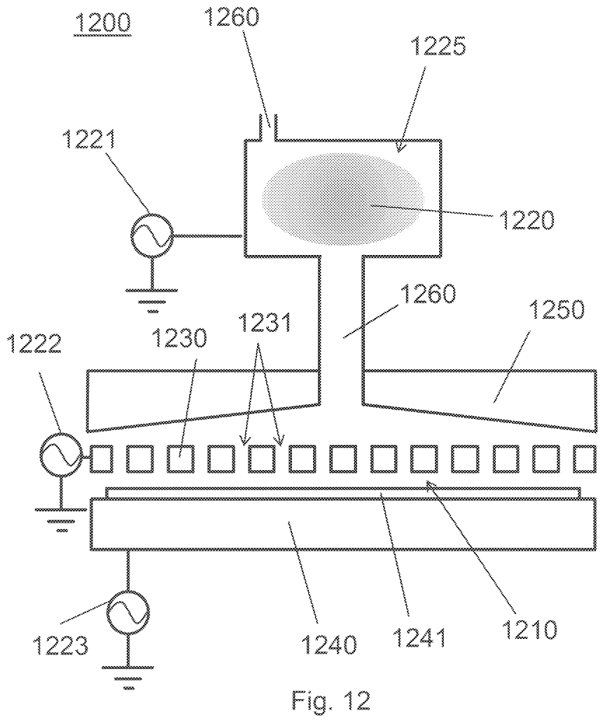

FIG. 12 shows a schematic representation of another embodiment of a system (1200) as described herein. The system (1200) comprises a reaction chamber (1210) which is operationally connected to a remote plasma source (1225) in which a plasma (1220) is generated. Any sort of plasma source can be used as a remote plasma source (1225), for example an inductively coupled plasma, a capacitively coupled plasma, or a microwave plasma.

In particular, active species are provided from the plasma source (1225) to the reaction chamber (1210) via an active species duct (1260), to a conical distributor (1250), through holes (1231) in a shower plate injector (1230), to the reaction chamber (1210). Thus, active species can be provided to the reaction chamber in a uniform way.

In the configuration shown, the system (1200) comprises three power sources: a first power source (1221), a second power source (1222), and a third power source (1223).

The first power source (1223) is a high frequency power source. It provides RF power to the remote plasma source (1225).

In some embodiments, the second power source (1222) is a high frequency power source and the third power source (1223) is also a high frequency power source. In such embodiments, a plasma can be suitably generated in the remote plasma source (1225), above the shower plate injector (1230), and in the reaction chamber (1210).

In some embodiments, the second power source (1222) is a low frequency power source and the third power source (1223) is another low frequency power source. In such embodiments, a plasma can be suitably generated in the remote plasma source (1225) only.

In some embodiments, the second power source (1222) is a low frequency power source and the third power source (1223) is a high frequency power source. In such embodiments, a plasma can be suitably generated in the remote plasma source (1225) and in the reaction chamber (1210).

In some embodiments, the second power source (1222) and the third power source (1223) can be omitted, or can be turned off. In such embodiments, a plasma can be suitably generated in the remote plasma source (1225) only.

In the configuration shown, the first power source (1221) supplies radio frequency (RF) power to the remote plasma source, the second power source (1222) supplies an alternating current to the shower plate injector (1230), and the third power source (1223) supplies an alternating current signal to the substrate support (1240). A substrate (1241) is provided on the substrate support (1240). The radio frequency power can be provided, for example, at a frequency of 13.56 MHz or higher. The low frequency alternating current signals can be provided, for example, at a frequency of 2 MHz or lower. RF power to the remote plasma source (1225) can be supplied, for example, at a frequency of 13.56 MHz in case the remote plasma source (1225) employs a capacitively coupled plasma, or at a frequency of 2.45 GHz in case the remote plasma source (1225) employs a microwave plasma.

Process gas comprising precursor, reactant, or both, is provided to the plasma source (1225) by means of a gas line (1260). Active species such as ions and radicals generated by the plasma (1225) from the process gas are guided to the reaction chamber (1210).

In a further exemplary embodiment, a method for filling a gap with a molybdenum-containing material is disclosed. First, a convertible layer is formed on a substrate comprising a gap by means of any suitable deposition technique, such as physical vapor deposition, chemical vapor deposition, plasma-enhanced atomic layer deposition, atomic layer deposition, plasma-enhanced chemical vapor deposition, etc. The convertible layer comprises molybdenum, for example metallic molybdenum, molybdenum oxide, molybdenum nitride, molybdenum oxynitride, or a mixture thereof. Then, the substrate is exposed to chlorine-containing active species. The chlorine-containing active species may, for example, include ions and radicals that comprise chlorine, and may be formed by a direct plasma system such as the system (1000) of FIG. 10. Alternatively, the chlorine-containing active species may consist of chlorine-containing radicals, which may be formed by an indirect plasma system such as the system (1100) of FIG. 11, or by a remote plasma system such as the system (1200) of FIG. 12. Thus, a chlorine and molybdenum-containing gap filling fluid can suitably be formed that can filled the gap under influence of surface tension and capillary forces. The substrate can then be exposed to a conversion treatment to convert the gap filling fluid, or a solidified material formed upon solidification of the gap filling fluid, to form a converted material. Suitable conversion treatments are disclosed herein. For example, exposing the substrate to a reducing agent such as H₂ can result in formation of metallic Mo; exposing the substrate to an oxidizing agent such as O₂ can result in formation of molybdenum oxide; and exposing the substrate to a nitridation agent such as NH₃ can result in formation of molybdenum nitride.

1. A system comprising:
a reaction chamber;
a precursor gas source comprising a metal precursor;
a deposition reactant gas source comprising a deposition reactant;
an active species source arranged for providing an active species;
a conversion reactant source arranged for providing a conversion reactant; and
a controller, wherein the controller is configured to control gas flow into the reaction chamber to form a layer on a substrate by:
depositing a convertible layer on a substrate; and
exposing the substrate to an active species, thereby converting at least a part of the convertible layer into a gap filling fluid,
wherein the gap filling fluid at least partially fills a gap on the substrate.

2. The system of claim 1, wherein the controller is further configured to provide a substrate to a reaction chamber.

3. The system of claim 1, further comprising a remote plasma source.

4. The system of claim 3, further comprising an active species duct between the remote plasma source and the reaction chamber.

5. The system of claim 4, wherein the active species duct comprises one or more mesh plates.

6. The system of claim 1, wherein the active species source is within the reaction chamber.

7. The system of claim 1, further comprising a showerhead injector and a substrate support.

8. The system of claim 7, wherein a plasma is generated between the showerhead injector and the substrate support.

9. The system of claim 7, further comprising a high frequency power source coupled to the showerhead injector.

10. The system of claim 7, further comprising a low frequency power source coupled to the showerhead injector.

11. The system of claim 7, further comprising a low frequency power source coupled to the substrate support.

12. The system of claim 11, further comprising a high frequency power source coupled to the substrate support.

13. The system of claim 7, wherein the reaction chamber is separated from a plasma generation space by the showerhead injector.

14. The system of claim 7, further comprising a grounded mesh plate between the showerhead injector and the substrate support.

15. The system of claim 7, further comprising a conical distributor coupled to the showerhead injector.

16. The system of claim 7, wherein the substrate support is grounded.

17. A system comprising:
a first reaction chamber;
a second reaction chamber;
a precursor gas source comprising a metal precursor;
a deposition reactant gas source comprising a deposition reactant;
an active species source arranged for providing an active species;
a conversion reactant source arranged for providing a conversion reactant; and
a controller, wherein the controller is configured to control gas flow into the first reaction chamber and the second reaction chamber to form a layer on a substrate by:
depositing a convertible layer on a substrate in the first reaction chamber; and
exposing the substrate to an active species in the second reaction chamber, thereby converting at least a part of the convertible layer into a gap filling fluid.

18. The system of claim 17, wherein the first reaction chamber is maintained at a first reaction chamber temperature, and the second reaction chamber is maintained at a second reaction chamber temperature higher or lower than the first reaction chamber temperature.

19. The system of claim 18, wherein the first reaction chamber temperature is from at least 10° C. lower to at most 100° C. lower than the second reaction chamber temperature.

20. The system of claim 18, wherein the first reaction chamber temperature is at least 10° C. higher to at most 100° C. higher than the second reaction chamber temperature.
